(19) United States
(12) Patent Application Publication
(10) Pub. No.: US 2026/0273758 A1
(43) Pub. Date: Sep. 17, 2026

(54) CONVEYANCE DEVICE

(71) Applicant: TDK CORPORATION, Tokyo (JP)

(72) Inventors: Mitsuyoshi MAKIDA, Tokyo (JP); Kazunari SO, Tokyo (JP); Yasuo KATO, Tokyo (JP)

(73) Assignee: TDK CORPORATION, Tokyo (JP)

(21) Appl. No.: 19/167,608

(22) PCT Filed: Mar. 19, 2024
(86) PCT No.: PCT/JP2024/010856

§ 371 Date: Jan. 16, 2026

(30) Foreign Application Priority Data
Mar. 20, 2023 (JP) 2023-044366

(51) Int. Cl. B25J 9/16; B25J 9/02; H05K 13/04

(52) U.S. Cl. CPC B25J 9/1697; B25J 9/026; H05K 13/0404

(57) ABSTRACT

A transfer apparatus includes a frame and a head fixed to the frame and configured to transfer a target. The frame includes an upper body provided with the head and curved in an arch shape toward a direction opposite a gravity direction.

### TECHNICAL FIELD

The present invention relates to a transfer apparatus.

### BACKGROUND

Various techniques (see, for example, Patent Document 1) have conventionally been suggested with regard to a transfer apparatus that transfers targets, such as electronic components. Such a transfer apparatus includes a frame and a head that is fixed to the frame and transfers targets using, for example, an adsorption means. The head takes targets from a first substrate (source) provided with the targets and mounts the targets at predetermined locations on a second substrate (destination).

The frame is composed of, for example, a metal member to ensure stiffness and has relatively heavy weight. Thus, the frame of the conventional transfer apparatus may be bent under its own weight to possibly cause variance in locations at which targets are mounted by the head.

### PRIOR ARTS

### Patent Document

Patent Document 1: JP Patent Application Laid Open No. 2013-254785

### SUMMARY OF INVENTION

### Problem to be Solved by Invention

The present invention has been achieved in view of such circumstances. It is an object of the invention to provide a transfer apparatus capable of mounting a target with high accuracy.

### Means for Solving the Problem

To achieve the above object, a transfer apparatus according to the present invention includes
a frame, and
a head fixed to the frame and configured to transfer a target,
wherein the frame includes an upper body provided with the head and curved in an arch shape toward a direction opposite a gravity direction.

The frame of the transfer apparatus according to the present invention includes the upper body provided with the head and curved in the arch shape toward the direction opposite the gravity direction. Thus, the weight of the upper body or external load (e.g., load applied by the head) applied to the upper body in the gravity direction is exerted on the upper body as compressive stress that compresses the upper body along its extending direction. This makes the upper body less prone to bending. This can prevent variance, attributed to a bend of the upper body, in locations at which targets are mounted by the head. Thus, according to the present invention, the transfer apparatus with which targets can be mounted with high accuracy can be achieved.

The upper body may include upper pillars in pairs and an upper beam provided with the head and bridging a space between the upper pillars in pairs. One end of the upper beam in its extending direction may continue to an end of one of the upper pillars in its axis direction. An other end of the upper beam in its extending direction may continue to an end of an other one of the upper pillars in its axis direction. The upper beam may be curved in an arch shape toward the direction opposite the gravity direction. In this situation, the curvature of the upper beam can be controlled while the lengths of the upper pillars in their axis direction can be controlled. This can optimize the height of the upper body along the gravity direction. At the same time, this can prevent a bend of the upper beam attributed to the weight of the upper beam or external load applied to the upper beam in the gravity direction.

An extremity of the head may be located lower than an installation surface of the upper pillars. In this situation, the center of gravity of the transfer apparatus can be located at a low location. Thus, this can stabilize the balance of the transfer apparatus to effectively prevent variance in locations at which targets are mounted by the head.

The upper beam may include a first branch part, a second branch part apart from the first branch part in a direction perpendicular to the gravity direction, and an opening extending along the gravity direction between the first branch part and the second branch part. Providing the upper beam with the opening can reduce the weight of the upper beam to prevent a bend of the upper beam attributed to its own weight. Providing the upper beam with the opening can also generate airflow (downflow) so that it passes through the opening from one side to an other side of the upper beam along the gravity direction. This can improve cleanliness of the atmosphere around the transfer apparatus to prevent substrate pollution attributed to dust or the like.

The frame may include a lower body supporting the upper body, and the lower body may be curved in an arch shape toward the direction opposite the gravity direction. In this situation, the weight of the lower body or external load (e.g., load applied by the upper body) applied to the lower body in the gravity direction is exerted on the lower body as compressive stress that compresses the lower body along its extending direction. This makes the lower body less prone to bending, enabling the lower body to firmly support the upper body. Consequently, there is less fluctuation of the location of the upper body along the gravity direction attributed to a bend of the lower body. This can effectively prevent variance in locations at which targets are mounted by the head.

The lower body may include lower pillars in pairs and a lower beam supporting the upper body and bridging a space between the lower pillars in pairs. One end of the lower beam in its extending direction may continue to an end of one of the lower pillars in its axis direction. An other end of the lower beam in its extending direction may continue to an end of an other one of the lower pillars in its axis direction. The lower beam may be curved in an arch shape toward the direction opposite the gravity direction. In this situation, the curvature of the lower beam can be controlled while the lengths of the lower pillars in their axis direction can be controlled. This can optimize the height of the lower body along the gravity direction. At the same time, this can prevent a bend of the lower beam attributed to the weight of the lower beam or external load applied to the lower beam in the gravity direction. This can also control the height of the frame as a whole along the gravity direction according to the lengths of the lower pillars in their axis direction.

The lower beam may be disposed orthogonal to the upper body. In this situation, it is possible for the lower beam to support the upper body in a well-balanced manner, enabling effective prevention of variance in locations at which targets are mounted by the head.

A camera module including an imaging part and a driving part may be three-dimensionally movably fixed to the lower beam. In this situation, the camera module can, at a desired location, take an image of a location at which a target is mounted by the head, conditions of a substrate on which the target is mounted, or the like.

The camera module may take an image of a location at which the target is mountable by the head and a location of an extremity of the head. In this situation, it is possible to align the location of the extremity of the head with an intended location at which the target is intended to be mounted (intended location) based on the location's imaging information obtained with the camera module, thereby enabling the head to mount the target at the intended location.

### BRIEF DESCRIPTION OF THE DRAWINGS

FIG. 1A is a perspective view of a transfer apparatus according to one embodiment of the present invention.

FIG. 1B is a side elevational view of the transfer apparatus shown in FIG. 1A viewed from the X-axis direction.

FIG. 2A is a perspective view of an upper body shown in FIG. 1A.

FIG. 2B is a perspective view of lower bodies shown in FIG. 1A.

FIG. 3 is a perspective view of the transfer apparatus shown in FIG. 1A, a first stage, a second stage, and a stand.

FIG. 4A is a perspective view illustrative of an operation of the transfer apparatus or the like.

FIG. 4B is a side elevational view of the transfer apparatus or the like shown in FIG. 4A.

FIG. 5A is a perspective view illustrative of a subsequent operation of the transfer apparatus or the like shown in FIG. 4A.

FIG. 5B is a side elevational view of the transfer apparatus or the like shown in FIG. 5A.

FIG. 6 is a side elevational view illustrative of a subsequent operation of the transfer apparatus or the like shown in FIG. 5A.

FIG. 7 is a side elevational view illustrative of a subsequent operation of the transfer apparatus or the like shown in FIG. 6.

FIG. 8A is a perspective view illustrative of a subsequent operation of the transfer apparatus or the like shown in FIG. 7.

FIG. 8B is a side elevational view of the transfer apparatus or the like shown in FIG. 8A.

FIG. 9 is a perspective view illustrative of a subsequent operation of the transfer apparatus or the like shown in FIG. 8A.

FIG. 10 is a perspective view illustrative of a subsequent operation of the transfer apparatus or the like shown in FIG. 9.

FIG. 11 is a perspective view of a modified example of the transfer apparatus shown in FIG. 1A.

### DETAILED DESCRIPTION OF INVENTION

Hereinafter, an embodiment of the present invention is described with reference to the drawings. Illustrations in the drawings are only schematically and exemplarily provided for understanding of the present invention; and the illustrated appearance, dimensional ratios, and the like may be different from actual ones. The present invention is not limited to the following embodiment.

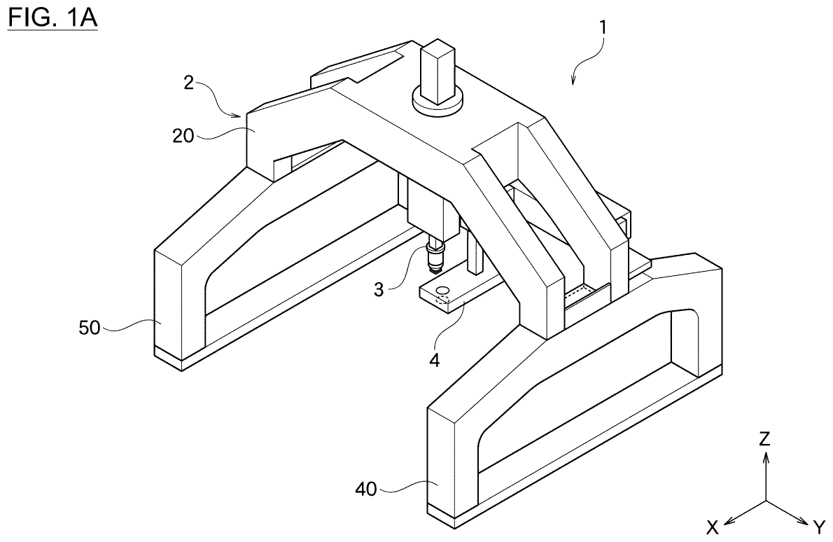

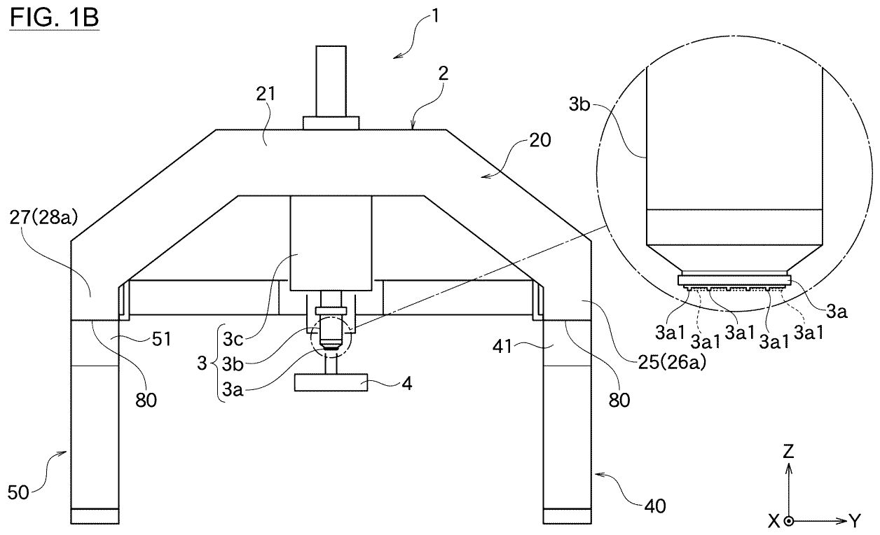

A transfer apparatus 1 according to one embodiment of the present invention shown in FIG. 1A is an apparatus that takes a target (e.g., an electronic component) from a transfer source and transfers the target to a transfer destination. The transfer apparatus 1 mounts the target on a substrate at the transfer destination. The transfer apparatus 1 may transfer, for example, electronic components such as capacitors, coils, and resistors. Among these electronic components, the transfer apparatus 1 may transfer surface mounting type electronic components. The transfer apparatus 1 may also transfer optical elements, such as LEDs. The transfer apparatus 1 may also transfer a joining material (an application material) for joining the above electronic components or elements to a substrate or the substrate having the above electronic components or elements disposed. Hereinafter, a target of the transfer apparatus 1 may be referred to as a “workpiece”.

The transfer apparatus 1 includes a frame 2 and a head 3 that is fixed to the frame 2 and transfers a workpiece. The transfer apparatus 1 may include a camera module 4 in addition to these constituent elements. The frame 2 is a mechanism for installing the head 3, arranging the head 3 at a desired height. The frame 2 includes an upper body 20. The frame 2 may include, in addition to the upper body 20, lower bodies 40 and 50 supporting the upper body 20.

Note that, in FIG. 1A or the like, the X-axis and the Y-axis are axis extending horizontally. In plan view, the X-axis extends along the extending direction (longitudinal direction) of the lower body 40 or 50, and the Y-axis extends along the extending direction (longitudinal direction) of the upper body 20. The Z-axis is an axis extending vertically. The negative direction of the Z-axis may be referred to as gravity direction.

To the upper body 20, the head 3 is fixed. The upper body 20 is not limited but is composed of highly stiff metal, such as steel use stainless (SUS) material, aluminum material, steel material, and cast metal. The upper body 20 has a modulus of stiffness (Young's modulus) of, for example, 69 GPa to 206 GPa. The length of the upper body 20 along the X-axis is not limited but is about 0.5 m. The length of the upper body 20 along the Y-axis (distance between the lower bodies 40 and 50 along the Y-axis) is not limited but is about 2 m. The height of the upper body 20 along the Z-axis is not limited but is about 0.7 m.

The upper body 20 has an arch shape (an arc shape, a C shape, or a half-ring shape) and is curved or bent in an arch shape (an arc shape, a C shape, or a half-ring shape) toward a direction opposite the gravity direction (i.e., toward the positive direction of the Z-axis). Thus, the upper body 20 has higher stiffness than, for example, an upper body 20 with a flat shape (extending along a horizontal plane). The head 3 may at least partly be disposed inside the arch provided by the upper body 20.

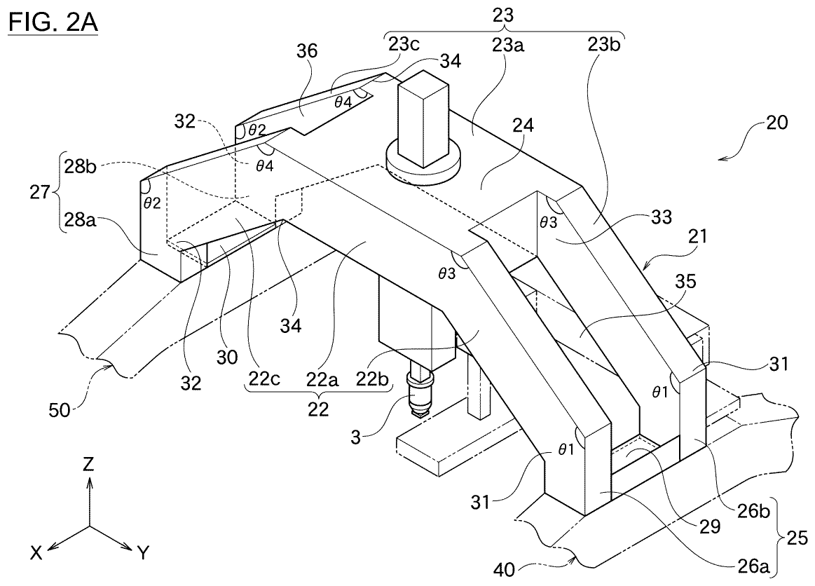

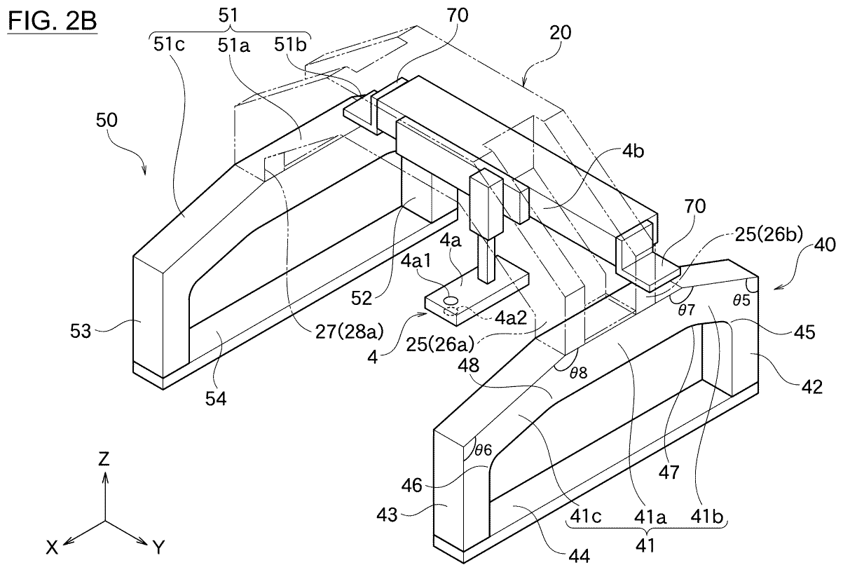

As shown in FIG. 2A, the upper body 20 may include an upper beam 21, an upper pillar 25, and an upper pillar 27. To a central portion of the upper beam 21 in the Y-axis direction, the head 3 is vertically movably fixed. The head 3 may be three-dimensionally movably fixed to the upper beam 21. The upper beam 21 has an arch shape (an arc shape, a C shape, or a half-ring shape) and is curved or bent in an arch shape (an arc shape, a C shape, or a half-ring shape) toward the direction opposite the gravity direction (i.e., toward the positive direction of the Z-axis).

The upper beam 21 bridges a space between the upper pillars 25 and 27 in pairs. One end of the upper beam 21 in its extending direction continues to an end (upper end) of the upper pillar 25 in its axis direction. The one end of the upper beam 21 in its extending direction and the upper pillar 25 may meet at a predetermined angle. In the present embodiment, bends 31 are provided where the upper beam 21 and the upper pillar 25 meet. As shown in FIG. 2A, 90°<θ1<180° is satisfied, where θ1 denotes the angle at which the upper beam 21 and the upper pillar 25 meet (angle formed at the bends 31 by the extending direction of the upper beam 21 and the axis direction of the upper pillar 25). While 120°<θ1<150° is satisfied in the present embodiment, the range of θ1 is not limited thereto.

An other end of the upper beam 21 in its extending direction continues to an end (upper end) of the upper pillar 27 in its axis direction. The other end of the upper beam 21 in its extending direction and the upper pillar 27 may meet at a predetermined angle. In the present embodiment, bends 32 are provided where the upper beam 21 and the upper pillar 27 meet. As shown in FIG. 2A, 90°<θ2<180° is satisfied, where 02 denotes the angle at which the upper beam 21 and the upper pillar 27 meet (angle formed at the bends 32 by the extending direction of the upper beam 21 and the axis direction of the upper pillar 27). While 120°<θ2<150° is satisfied in the present embodiment, the range of θ2 is not limited thereto. θ1 and θ2 are equivalent to each other but may be different.

The upper beam 21 and the upper pillar 25 may be smoothly curved. Similarly, the upper beam 21 and the upper pillar 27 may be smoothly curved. The upper beam 21 and the upper pillar 25 are integrally provided but may be separately provided. Similarly, the upper beam 21 and the upper pillar 27 are integrally provided but may be separately provided. Alternatively, the upper pillars 25 and 27 may be omitted from the upper body 20, and the upper beam 21 may be directly fixed to the lower bodies 40 and 50.

The upper beam 21 may include a first branch part 22 and a second branch part 23, which is apart from the first branch part 22 in the X-axis direction. The first branch part 22 and the second branch part 23 are disposed in parallel along the Y-axis. The first branch part 22 and the second branch part 23 each have an arch shape (an arc shape, a C shape, or a half-ring shape) and are curved or bent in an arch shape (an arc shape, a C shape, or a half-ring shape) toward the direction opposite the gravity direction (i.e., toward the positive direction of the Z-axis). The upper beam 21 includes two branch parts in the present embodiment but may include three or more branch parts. Alternatively, it may be that the upper beam 21 does not have a branching structure.

The first branch part 22 may include a top portion 22a, a side portion 22b, and a side portion 22c. Among portions of the first branch part 22, the top portion 22a is located at a highest location along the Z-axis. The top portion 22a extends along the Y-axis and is disposed parallel to a horizontal plane (an XY plane). However, the top portion 22a may have a curved structure or a bent structure. The top portion 22a may, for example, have an arch shape (an arc shape, a C shape, or a half-ring shape) curved or bent in an arch shape (an arc shape, a C shape, or a half-ring shape) toward the direction opposite the gravity direction (i.e., toward the positive direction of the Z-axis).

The side portion 22b extends in the gravity direction in a tilted manner relative to the Y-axis. One end of the side portion 22b in its axis direction continues to one end of the top portion 22a in the Y-axis direction, whereas an other end of the side portion 22b in its axis direction continues to the end (upper end) of the upper pillar 25 (pillar body 26a) in its axis direction.

The top portion 22a and the side portion 22b may meet at a predetermined angle. In the present embodiment, a bend 33 is provided where the top portion 22a and the side portion 22b meet. As shown in FIG. 2A, 90°<θ3<180° is satisfied, where θ3 denotes the angle at which the top portion 22a and the side portion 22b meet. While 130°<θ3<160° is satisfied in the present embodiment, the range of θ3 is not limited thereto.

The side portion 22c extends in the gravity direction in a tilted manner relative to the Y-axis. One end of the side portion 22c in its axis direction continues to an other end of the top portion 22a in the Y-axis direction, whereas an other end of the side portion 22c in its axis direction continues to the end (upper end) of the upper pillar 27 (pillar body 28a) in its axis direction.

The top portion 22a and the side portion 22c may meet at a predetermined angle. In the present embodiment, a bend 34 is provided where the top portion 22a and the side portion 22c meet. As shown in FIG. 2A, 90°<θ4<180° is satisfied, where θ4 denotes the angle at which the top portion 22a and the side portion 22c meet. While 130°<θ4<160° is satisfied in the present embodiment, the range of θ4 is not limited thereto.

θ3 and θ4 are equivalent to each other but may be different. The top portion 22a and the side portion 22b may be smoothly curved. Similarly, the top portion 22a and the side portion 22c may be smoothly curved.

The second branch part 23 may include a top portion 23a, a side portion 23b, and a side portion 23c. Among portions of the second branch part 23, the top portion 23a is located at a highest location along the Z-axis. The top portion 23a extends along the Y-axis and is disposed parallel to a horizontal plane. However, the top portion 23a may have a curved structure or a bent structure. The top portion 23a may, for example, have an arch shape (an arc shape, a C shape, or a half-ring shape) curved or bent in an arch shape (an arc shape, a C shape, or a half-ring shape) toward the direction opposite the gravity direction (i.e., toward the positive direction of the Z-axis).

The side portion 23b extends in the gravity direction in a tilted manner relative to the Y-axis. One end of the side portion 23b in its axis direction continues to one end of the top portion 23a in the Y-axis direction, whereas an other end of the side portion 23b in its axis direction continues to the end (upper end) of the upper pillar 25 (pillar body 26b) in its axis direction.

The top portion 23a and the side portion 23b may meet at a predetermined angle. In the present embodiment, a bend 33 is provided where the top portion 23a and the side portion 23b meet. As shown in FIG. 2A, the angle at which the top portion 23a and the side portion 23b meet may be similar to the angle (θ3) at which the top portion 22a and the side portion 22b meet.

The side portion 23c extends in the gravity direction in a tilted manner relative to the Y-axis. One end of the side portion 23c in its axis direction continues to an other end of the top portion 23a in the Y-axis direction, whereas an other end of the side portion 23c in its axis direction continues to the end (upper end) of the upper pillar 27 (pillar body 28b) in its axis direction.

The top portion 23a and the side portion 23c may meet at a predetermined angle. In the present embodiment, a bend 34 is provided where the top portion 23a and the side portion 23c meet. The angle at which the top portion 23a and the side portion 23c meet may be similar to the angle (θ4) at which the top portion 22a and the side portion 22c meet.

θ3 and θ4 are equivalent to each other but may be different. The top portion 23a and the side portion 23b may be smoothly curved. Similarly, the top portion 23a and the side portion 23c may be smoothly curved.

The upper body 20 may further include or have a head fixing part 24, an opening 35, and an opening 36. The head fixing part 24 is located between the top portions 22a and 23a. While the head fixing part 24 is a plate body disposed parallel to a horizontal plane in the present embodiment, the structure of the head fixing part 24 is not limited. The head fixing part 24 is integrated with the first branch part 22 (top portion 22a) and the second branch part 23 (top portion 23a) but may be provided separately from the first branch part 22 (top portion 22a) or the second branch part 23 (top portion 23a). To the head fixing part 24, the head 3 is fixed.

The opening 35 is provided between the side portions 22b and 23b. The opening 35 extends along the gravity direction, between the first branch part 22 and the second branch part 23. The number of the opening 35 is one but may be plural. Alternatively, the opening 35 may be omitted from the upper body 20. The opening 35 has a rectangular shape but may have a circular shape, an oval shape, a square shape, or other polygonal shape.

The opening 36 is provided between the side portions 22c and 23c. The opening 36 extends along the gravity direction, between the first branch part 22 and the second branch part 23. The number of the opening 36 is one but may be plural. Alternatively, the opening 36 may be omitted from the upper body 20. The opening 36 has a rectangular shape but may have a circular shape, an oval shape, a square shape, or other polygonal shape.

Providing the upper beam 21 with the openings 35 and 36 can generate airflow (downflow) so that it passes through the openings 35 and 36 from one side to an other side of the upper beam 21 along the gravity direction. This can improve cleanliness of the atmosphere around the transfer apparatus 1 (FIG. 1A) to prevent substrate pollution attributed to dust or the like. Additionally, this can reduce the weight of the upper beam 21.

The upper pillars 25 and 27 extend in the vertical direction and have the same length. The upper pillars 25 and 27 are mechanisms for mainly controlling the height position of the upper beam 21 along the Z-axis. While the height position of the upper pillar 25 is lower than the height position of the upper beam 21 in the Z-axis direction in the present embodiment, the height positions may be equivalent to each other. Alternatively, the height position of the upper pillar 25 may be higher than the height position of the upper beam 21. This can control stiffness of the upper body 20. The same applies to the upper pillar 27.

The upper pillar 25 may include the pillar bodies 26a and 26b. The pillar bodies 26a and 26b have the same shape and are apart in the X-axis direction. The end (upper end) of the pillar body 26a in its axis direction continues to the side portion 22b of the first branch part 22. The end (upper end) of the pillar body 26b in its axis direction continues to the side portion 23b of the second branch part 23. Between the pillar bodies 26a and 26b is a space along the X-axis. This space is connected to a space inward from the opening 35. The upper pillar 25 may include one pillar body. Alternatively, the upper pillar 25 may include three or more pillar bodies.

The upper pillar 27 may include the pillar bodies 28a and 28b. The pillar bodies 28a and 28b have the same shape and are apart in the X-axis direction. The end (upper end) of the pillar body 28a in its axis direction continues to the side portion 22c of the first branch part 22. The end (upper end) of the pillar body 28b in its axis direction continues to the side portion 23c of the second branch part 23. Between the pillar bodies 28a and 28b is a space along the X-axis. This space is connected to a space inward from the opening 36. The upper pillar 27 may include one pillar body. Alternatively, the upper pillar 27 may include three or more pillar bodies.

The upper body 20 may include an upper fixing part 29 connecting the pillar bodies 26a and 26b and an upper fixing part 30 connecting the pillar bodies 28a and 28b. The upper fixing part 29 includes a plate body parallel to a horizontal plane. This plate body connects an end (a lower end) of the pillar body 26a in its axis direction and an end (a lower end) of the pillar body 26b in its axis direction. The upper fixing part 29 includes a plate body parallel to an XZ plane. This plate body connects the pillar bodies 26a and 26b. However, the structure of the upper fixing part 29 is not limited to the structure shown in FIG. 2A. The upper body 20 is fixed to the lower body 40 using the upper pillar 25 and the upper fixing part 29. The upper fixing part 29 is a supplementary structure for stably arranging the upper body 20 on the lower body 40. The upper fixing part 29 may be omitted from the upper body 20.

The upper fixing part 30 includes a plate body parallel to a horizontal plane. This plate body connects an end (a lower end) of the pillar body 28a in its axis direction and an end (a lower end) of the pillar body 28b in its axis direction. Alternatively, the upper fixing part 30 may include a plate body parallel to an XZ plane to connect the pillar bodies 28a and 28b. However, the structure of the upper fixing part 30 is not limited to the structure shown in FIG. 2A. The upper body 20 is fixed to the lower body 50 using the upper pillar 27 and the upper fixing part 30. The upper fixing part 30 is a supplementary structure for stably arranging the upper body 20 on the lower body 50. The upper fixing part 30 may be omitted from the upper body 20.

As shown in FIG. 2B, the lower bodies 40 and 50 support the upper body 20. The lower bodies 40 and 50 are separately provided but may be integrally provided. The lower bodies 40 and 50 have the same shape but may have different shapes. The lower bodies 40 and 50 are composed of members similar to the upper body 20 but may be composed of members different from the upper body 20. The length of the lower body 40 along the X-axis is not limited but is about 1.8 m. The length of the lower body 40 along the Y-axis is not limited but is about 0.2 m. The height of the lower body 40 along the Z-axis is not limited but is about 0.8 m. The same applies to the lower body 50.

The lower body 40 at least partly has an arch shape (an arc shape, a C shape, or a half-ring shape) and is curved or bent in an arch shape (an arc shape, a C shape, or a half-ring shape) toward the direction opposite the gravity direction (i.e., toward the positive direction of the Z-axis).

The lower body 40 may include a lower beam 41, a lower pillar 42, and a lower pillar 43. To a central portion of the lower beam 41 in the X-axis direction, the upper pillar 25 of the upper body 20 is directly or indirectly fixed. The upper pillar 25 may be welded to the lower beam 41. The lower beam 41 has an arch shape (an arc shape, a C shape, or a half-PCT ring shape) and is curved or bent in an arch shape (an arc shape, a C shape, or a half-ring shape) toward the direction opposite the gravity direction (i.e., toward the positive direction of the Z-axis). Thus, the lower beam 41 has higher stiffness than, for example, a lower beam 41 with a flat shape (extending along a horizontal plane).

The lower beam 41 bridges a space between the lower pillars 42 and 43 in pairs. The lower beam 41 is disposed orthogonal to the upper body 20 along the X-axis and supports the upper body 20. One end of the lower beam 41 in its extending direction continues to an end (upper end) of the lower pillar 42 in its axis direction. The one end of the lower beam 41 in its extending direction and the lower pillar 42 may meet at a predetermined angle. In the present embodiment, a bend 45 is provided where the lower beam 41 and the lower pillar 42 meet. As shown in FIG. 2B, 90°<θ5<180° is satisfied, where θ5 denotes the angle at which the lower beam 41 and the lower pillar 42 meet (angle formed at the bend 45 by the extending direction of the lower beam 41 and the axis direction of the lower pillar 42). While 100°<θ5<130° is satisfied in the present embodiment, the range of θ5 is not limited thereto.

An other end of the lower beam 41 in its extending direction continues to an end (upper end) of the lower pillar 43 in its axis direction. The other end of the lower beam 41 in its extending direction and the lower pillar 43 may meet at a predetermined angle. In the present embodiment, a bend 46 is provided where the lower beam 41 and the lower pillar 43 meet. As shown in FIG. 2B, 90°<θ6<180° is satisfied, where θ6 denotes the angle at which the lower beam 41 and the lower pillar 43 meet (angle formed at the bend 46 by the extending direction of the lower beam 41 and the axis direction of the lower pillar 43). While 100°<θ6<130° is satisfied in the present embodiment, the range of θ6 is not limited thereto. θ5 and θ6 are equivalent to each other but may be different.

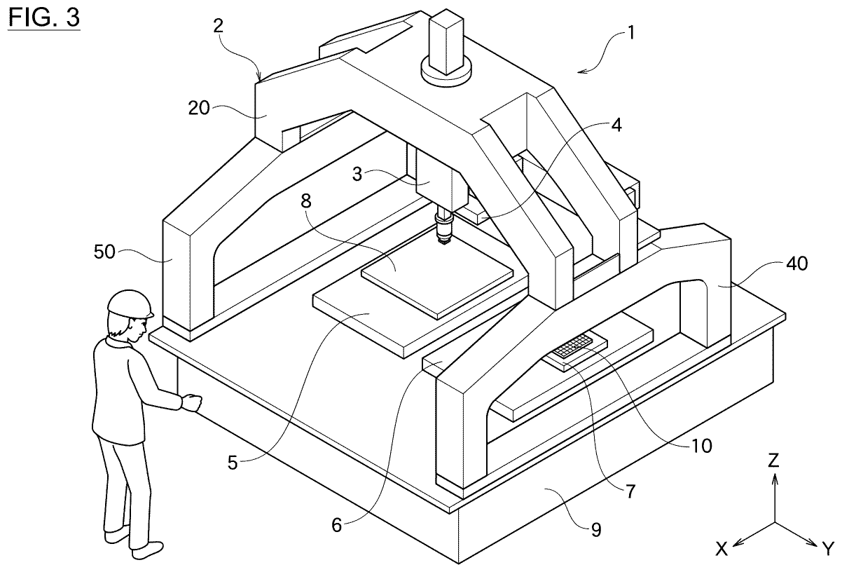

The lower beam 41 and the lower pillar 42 may be smoothly curved. Similarly, the lower beam 41 and the lower pillar 43 may be smoothly curved. The lower beam 41 and the lower pillar 42 are integrally provided but may be separately provided. Similarly, the lower beam 41 and the lower pillar 43 are integrally provided but may be separately provided. Alternatively, the lower pillars 42 and 43 may be omitted from the lower body 40, and the lower beam 41 may be directly fixed to a stand (see a stand 9 shown in FIG. 3). Similarly to the upper beam 21 (FIG. 2A), the lower beam 41 may have a branching structure.

The lower beam 41 may include a top portion 41a, a side portion 41b, and a side portion 41c. Among portions of the lower beam 41, the top portion 41a is located at a highest location along the Z-axis. The top portion 41a extends along the X-axis and is disposed parallel to a horizontal plane. However, the top portion 41a may have a curved structure or a bent structure. The top portion 41a may, for example, have an arch shape (an arc shape, a C shape, or a half-ring shape) curved or bent in an arch shape (an arc shape, a C shape, or a half-ring shape) toward the direction opposite the gravity direction (i.e., toward the positive direction of the Z-axis).

The side portion 41b extends in the gravity direction in a tilted manner relative to the X-axis. One end of the side portion 41b in its axis direction continues to one end of the top portion 41a in the X-axis direction, whereas an other end of the side portion 41b in its axis direction continues to the end (upper end) of the lower pillar 42 in its axis direction.

The top portion 41a and the side portion 41b may meet at a predetermined angle. In the present embodiment, a bend 47 is provided where the top portion 41a and the side portion 41b meet. As shown in FIG. 2B, 90°<θ7<180° is satisfied, where θ7 denotes the angle at which the top portion 41a and the side portion 41b meet. While 140°<θ7<170° is satisfied in the present embodiment, the range of θ7 is not limited thereto.

The side portion 41c extends in the gravity direction in a tilted manner relative to the X-axis. One end of the side portion 41c in its axis direction continues to an other end of the top portion 41a in the X-axis direction, whereas an other end of the side portion 41c in its axis direction continues to the end (upper end) of the lower pillar 43 in its axis direction.

The top portion 41a and the side portion 41c may meet at a predetermined angle. In the present embodiment, a bend 48 is provided where the top portion 41a and the side portion 41c meet. As shown in FIG. 2B, 90°<θ8<180° is satisfied, where θ8 denotes the angle at which the top portion 41a and the side portion 41c meet. While 140°<θ8<170° is satisfied in the present embodiment, the range of θ8 is not limited thereto.

θ7 and θ8 are equivalent to each other but may be different. The top portion 41a and the side portion 41b may be smoothly curved. Similarly, the top portion 41a and the side portion 41c may be smoothly curved.

The lower pillars 42 and 43 have the same shape and are apart in the X-axis direction. The lower pillars 42 and 43 extend in the vertical direction (Z-axis direction) and have the same length. The lower pillars 42 and 43 are mechanisms for fixing the lower body 40 to corners of the stand (see the stand 9 in FIG. 3). Additionally, the lower pillars 42 and 43 are mechanisms for controlling the height position of the lower beam 41 along the Z-axis. While the height of the lower pillar 42 is larger than the height of the lower beam 41 in the Z-axis direction in the present embodiment, the heights may be equivalent to each other. Alternatively, the height of the lower pillar 42 may be larger than the height of the lower beam 41. This can control stiffness of the lower body 40. The same applies to the lower pillar 43.

The end (upper end) of the lower pillar 42 in its axis direction continues to the side portion 41b. The end (upper end) of the lower pillar 43 in its axis direction continues to the side portion 41c. The lower pillar 42 includes one pillar body but may include multiple pillar bodies. Similarly, the lower pillar 43 includes one pillar body but may include multiple pillar bodies.

The lower body 40 may include a lower fixing part 44 connecting the lower pillars 42 and 43. The lower fixing part 44 includes a plate body parallel to a horizontal plane. This plate body connects an end (a lower end) of the lower pillar 42 in its axis direction and an end (a lower end) of the lower pillar 43 in its axis direction. However, the structure of the lower fixing part 44 is not limited to the structure shown in FIG. 2B. The lower body 40 is fixed to the stand (see the stand 9 in FIG. 3) using the lower fixing part 44. The lower fixing part 44 is a supplementary structure for stably arranging the lower body 40 on the stand. The lower fixing part 44 may be omitted from the lower body 40 to arrange the lower pillars 42 and 43 directly on the stand.

The lower body 50 has an arch shape (an arc shape, a C shape, or a half-ring shape) and is curved or bent in an arch shape (an arc shape, a C shape, or a half-ring shape) toward the direction opposite the gravity direction (i.e., toward the positive direction of the Z-axis).

The lower body 50 may include a lower beam 51, a lower pillar 52, and a lower pillar 53. Structures of the lower beam 51, the lower pillar 52, and the lower pillar 53 of the lower body 50 are the same as the structures of the lower beam 41, the lower pillar 42, and the lower pillar 43 of the lower body 40, respectively. Thus, the above description of the lower beam 41, the lower pillar 42, and the lower pillar 43 applies to the lower beam 51, the lower pillar 52, and the lower pillar 53. Detailed description of the structures of the lower beam 51, the lower pillar 52, and the lower pillar 53 is omitted unless it is necessary.

The lower beam 51 bridges a space between the lower pillars 52 and 53 in pairs. The lower beam 51 is disposed orthogonal to the upper body 20 along the X-axis and supports the upper body 20. To a central portion of the lower beam 51 in the X-axis direction, the upper pillar 27 of the upper body 20 is directly or indirectly fixed. The upper pillar 27 may be welded to the lower beam 51. The lower beam 51 has an arch shape (an arc shape, a C shape, or a half-ring shape) and is curved or bent in an arch shape (an arc shape, a C shape, or a half-ring shape) toward the direction opposite the gravity direction (i.e., toward the positive direction of the Z-axis).

The lower beam 51 may include a top portion 51a, a side portion 51b, and a side portion 51c. Structures of the top portion 51a, the side portion 51b, and the side portion 51c of the lower beam 51 are the same as the structures of the top portion 41a, the side portion 41b, and the side portion 41c of the lower beam 41, respectively. Thus, the above description of the top portion 41a, the side portion 41b, and the side portion 41c applies to the top portion 51a, the side portion 51b, and the side portion 51c. Detailed description of the structures of the top portion 51a, the side portion 51b, and the side portion 51c is omitted unless it is necessary.

The top portion 51a extends along the X-axis and is disposed parallel to a horizontal plane. However, the top portion 51a may have a curved structure or a bent structure. The top portion 51a may, for example, have an arch shape (an arc shape, a C shape, or a half-ring shape) curved or bent in an arch shape (an arc shape, a C shape, or a half-ring shape) toward the direction opposite the gravity direction (i.e., toward the positive direction of the Z-axis).

Structures of the lower pillars 52 and 53 of the lower body 50 are the same as the structures of the lower pillars 42 and 43 of the lower body 40, respectively. Thus, the above description of the lower pillars 42 and 43 applies to the lower pillars 52 and 53. Detailed description of the structures of the lower pillars 52 and 53 is omitted unless it is necessary.

The lower body 50 may include a lower fixing part 54 connecting the lower pillars 52 and 53. The lower fixing part 54 includes a plate body parallel to a horizontal plane. This plate body connects an end (a lower end) of the lower pillar 52 in its axis direction and an end (a lower end) of the lower pillar 53 in its axis direction. However, the structure of the lower fixing part 54 is not limited to the structure shown in FIG. 2B. The lower body 50 is fixed to the stand (see the stand 9 in FIG. 3) using the lower fixing part 54. The lower fixing part 54 is a supplementary structure for stably arranging the lower body 50 on the stand. The lower fixing part 54 may be omitted from the lower body 50 to arrange the lower pillars 52 and 53 directly on the stand.

As shown in FIG. 1B, the head 3 is fixed to the upper beam 21 so as to be hangable from the upper beam 21. The head 3 is movable along the Z-axis. The head 3 moves, for example, back and forth in the Z-axis direction along a shaft extending in the vertical direction. However, the head 3 may be three-dimensionally movable along the X-axis, the Y-axis, and the Z-axis. The head 3 includes a workpiece holding part 3a; a base 3b, which is provided with the workpiece holding part 3a; and a driving part 3c, which drives the base 3b.

The workpiece holding part 3a takes a workpiece from a first substrate, which is a transfer source with the workpiece prepared, and mounts the workpiece at a predetermined location on a second substrate, which is a transfer destination. In the present embodiment, the workpiece holding part 3a holds the workpiece using adhesion. However, the workpiece holding part 3a may use suction, adsorption (e.g., vacuum adsorption or electrostatic adsorption), or the like to make the workpiece adhere to the workpiece holding part 3a. In this situation, the workpiece holding part 3a may include a nozzle suitable for suction or adsorption. In a situation where the workpiece itself has viscosity, the workpiece holding part 3a may use the viscosity of the workpiece itself to make the workpiece adhere to the workpiece holding part 3a.

The workpiece holding part 3a may be detachably attached to the base 3b. Alternatively, the workpiece holding part 3a and the base 3b may be integrally provided. Also, the workpiece holding part 3a may include protrusions 3a1 as a structure for holding workpieces. The protrusions 3a1 protrude downward (in the gravity direction) from a lower surface of the workpiece holding part 3a.

The protrusions 3a1 are composed of, for example, material with adhesiveness and can hold workpieces disposed on a substrate using adhesion. Materials of the protrusions 3a1 are not limited. Examples of the materials include polydimethylsiloxane (PDMS), organic silicon compounds, and viscoelastic elastomers (e.g., polyether rubber).

The protrusions 3a1 may be disposed in a matrix along the X-axis and the Y-axis at predetermined intervals. Using adhesion, the protrusions 3a1 hold the workpieces disposed on a substrate in a matrix. The protrusions 3a1 may be disposed randomly.

An extremity of the head 3 (the workpiece holding part 3a or at least a portion of the base 3b) may be located lower than an installation surface 80 of the upper pillar 25 of the upper body 20 (faying surface between the upper pillar 25 and the lower beam 41). Similarly, the extremity of the head 3 (the workpiece holding part 3a or at least a portion of the base 3b) may be located lower than an installation surface 80 of the upper pillar 27 of the upper body 20 (faying surface between the upper pillar 27 and the lower beam 51).

Alternatively, the extremity of the head 3 (the workpiece holding part 3a or at least a portion of the base 3b) may move from a location higher than the installation surface 80 of the upper pillar 25 (faying surface between the upper pillar 25 and the lower beam 41) to a location lower than the installation surface 80 using driving of the driving part 3c. Similarly, the extremity of the head 3 (the workpiece holding part 3a or at least a portion of the base 3b) may move from a location higher than the installation surface 80 of the upper pillar 27 (faying surface between the upper pillar 27 and the lower beam 51) to a location lower than the installation surface 80 using driving of the driving part 3c.

As shown in FIG. 3, in the present embodiment, the head 3 is fixed to the frame 2, which is large in size and includes the upper body 20 and the lower bodies 40 and 50. The frame 2 weigh, for example, 800 kg to 1200 kg. In contrast, a workpiece 10, which is a target of transfer by the head 3, is relatively tiny (e.g., a several um order size). The head 3 (in particular, the workpiece holding part 3a or the base 3b shown in FIG. 1B) has a shape (dimensions) sufficient for transferring such a workpiece 10, i.e., a shape with a size smaller than that of the frame 2 and smaller than that of a human body shown in FIG. 3. Fixing the head 3 (in particular, the workpiece holding part 3a or the base 3b) with a small size to the frame 2 with such a large size can prevent a bend of the frame 2 to prevent variance in locations at which workpieces 10 are mounted by the head 3.

As shown in FIG. 2B, the camera module 4 includes an imaging part 4a and a driving part 4b, which drives the imaging part 4a. The camera module 4 is disposed in the vicinity of the head 3. The imaging part 4a is a dual field of view camera and includes a first lens 4a1 for imaging a portion above the imaging part 4a and a second lens 4a2 for imaging a portion below the imaging part 4a. However, the number of lenses of the imaging part 4a is not limited. The imaging part 4a may be three-dimensionally movable along the X-axis, the Y-axis, and the Z-axis. The camera module 4 is fixed to the lower beams 41 and 51 using jigs 70. However, the camera module 4 may be directly fixed to the lower beams 41 and 51.

In the present embodiment, the driving part 4b is partly fixed to the lower beams 41 and 51 using the two jigs 70. The imaging part 4a is fixed to the driving part 4b so as to be hangable from the driving part 4b. However, the structures of the imaging part 4a and the driving part 4b are not limited to the structures shown in FIG. 2B.

The imaging part 4a moves back and forth in the X-axis direction along, for example, a shaft extending in the X-axis direction. The imaging part 4a also moves back and forth in the Y-axis direction along, for example, a shaft extending in the Y-axis direction. The imaging part 4a also moves back and forth in the Z-axis direction along, for example, a shaft extending in the Z-axis direction.

Using the first lens 4a1, at a desired location, the imaging part 4a takes an image of a location of the extremity of the head 3 (location of the workpiece holding part 3a) or the like. Using the second lens 4a2, at a desired location, the imaging part 4a takes an image of a location at which a workpiece 10 is mounted by the head 3, conditions of a substrate on which the workpiece 10 is mounted, or the like. Imaging information obtained by imaging by the imaging part 4a is transmitted to a controller (not shown in the drawings) of the transfer apparatus 1. In the present embodiment, it is possible to accurately align the location of the extremity of the head 3 (location of the workpiece holding part 3a) with an intended location at which the workpiece 10 is intended to be mounted based on the imaging information obtained by imaging by the imaging part 4a, thereby enabling the head 3 to mount the workpiece 10 at the intended location.

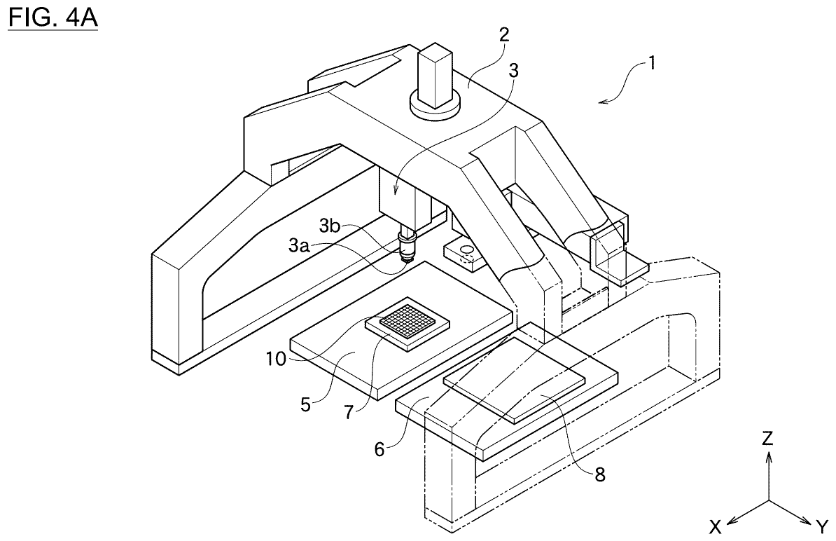

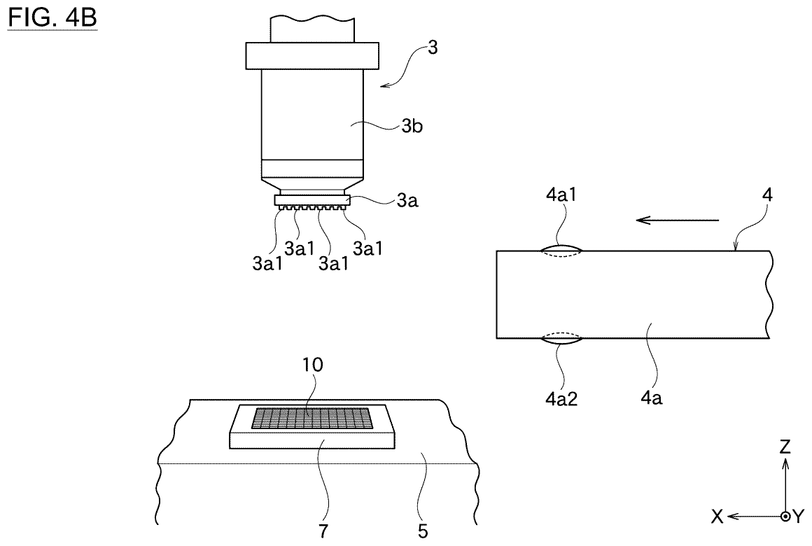

Now, operations of the transfer apparatus 1 are described below with reference to FIGS. 4A to 9. Described below are steps of taking workpieces 10 from a first substrate 7 (transfer source) on which the workpieces 10 are disposed and mounting the workpieces 10 at predetermined locations on a second substrate 8 (transfer destination) using the head 3 shown in FIG. 4A. As shown in FIG. 4A, the workpieces 10 are disposed on the first substrate 7. The first substrate 7 is disposed on a first stage 5, which is freely movable along, for example, the X-axis and the Y-axis. The first substrate 7 has a square shape in plan view but may have a circular shape, an oval shape, a rectangular shape, or other polygonal shape. The second substrate 8 is disposed on a second stage 6, which is freely movable along, for example, the X-axis and the Y-axis. The second substrate 8 has a square shape in plan view but may have a circular shape, an oval shape, a rectangular shape, or other polygonal shape. As shown in FIG. 3, the first stage 5 and the second stage 6 are directly or indirectly disposed on the stand 9.

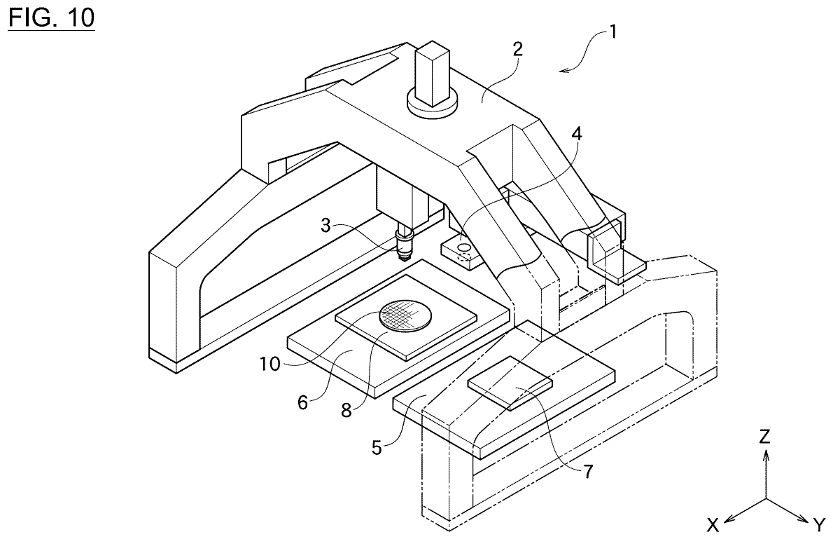

As shown in FIG. 4A, first, the first stage 5 with the first substrate 7 moves from a predetermined location (e.g., location shown in FIG. 10) to a location below the head 3. As the first substrate 7 is disposed directly below the head 3, the first stage 5 stops and waits at that location. The second stage 6 with the second substrate 8 moves from a predetermined location (e.g., location shown in FIG. 10) to a location away from the head 3 (e.g., location adjacent to that of the first stage 5) and waits at that location. As shown in FIG. 4B, the camera module 4 waits at, for example, a location away from the first substrate 7 in the X-axis direction.

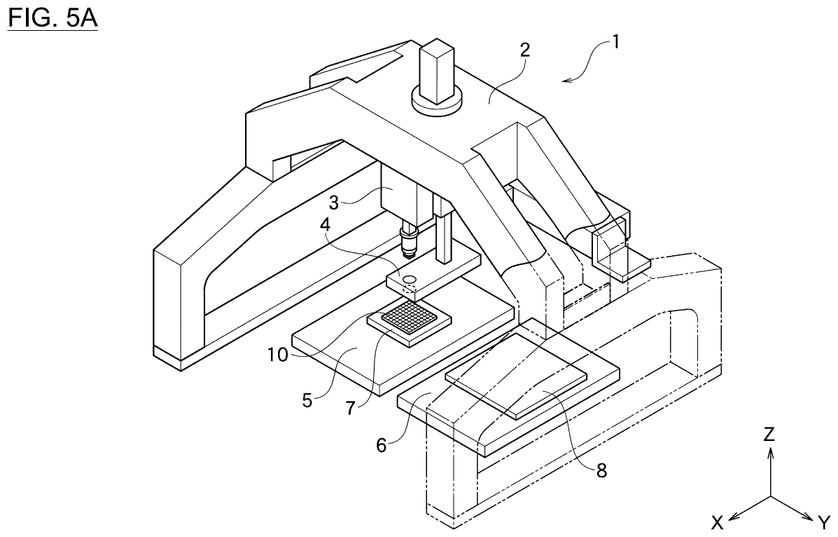

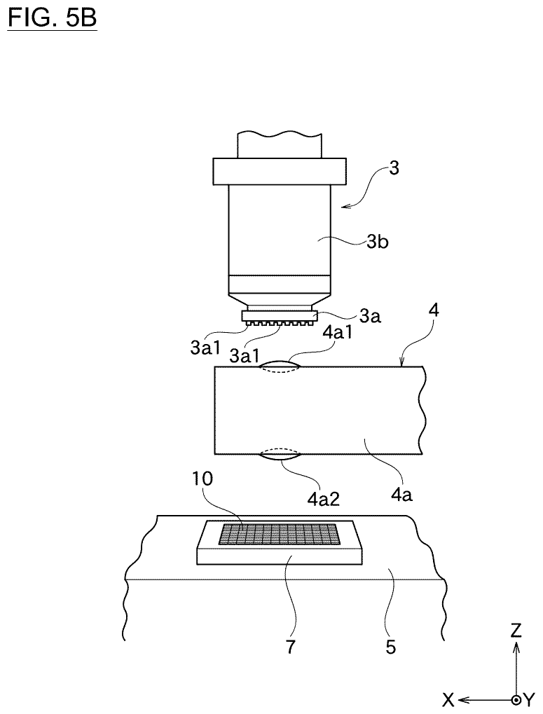

Then, the camera module 4 proceeds in the direction of an arrow in FIG. 4B along the X-axis. As the imaging part 4a (the first lens 4a1 and the second lens 4a2) is disposed directly below the head 3 as shown in FIGS. 5A and 5B, the camera module 4 stops and takes an image at that location using the imaging part 4a. Using the first lens 4a1, the imaging part 4a takes an image of the location of the extremity of the head 3 (location of the workpiece holding part 3a) or the like. Using the second lens 4a2, the imaging part 4a takes an image of the locations of the workpieces 10 mounted on the first substrate 7, conditions of the first substrate 7 on which the workpieces 10 are mounted, or the like. The camera module 4 transmits imaging information obtained by imaging by the imaging part 4a to the controller (not shown in the drawings) of the transfer apparatus 1.

In a situation where, for example, the location of the extremity of the head 3 (location of the workpiece holding part 3a) is misaligned in the X-axis direction or the Y-axis direction relative to the locations of the workpieces 10 disposed on the first substrate 7, the controller transmits a control signal to the first stage 5 to control the location of the first stage 5 in the X-axis direction or the Y-axis direction. This enables the first substrate 7 on the first stage 5 to be disposed directly below the head 3. Note that the controller may transmit a control signal to the head 3 to control the location of the head 3 in the X-axis direction or the Y-axis direction.

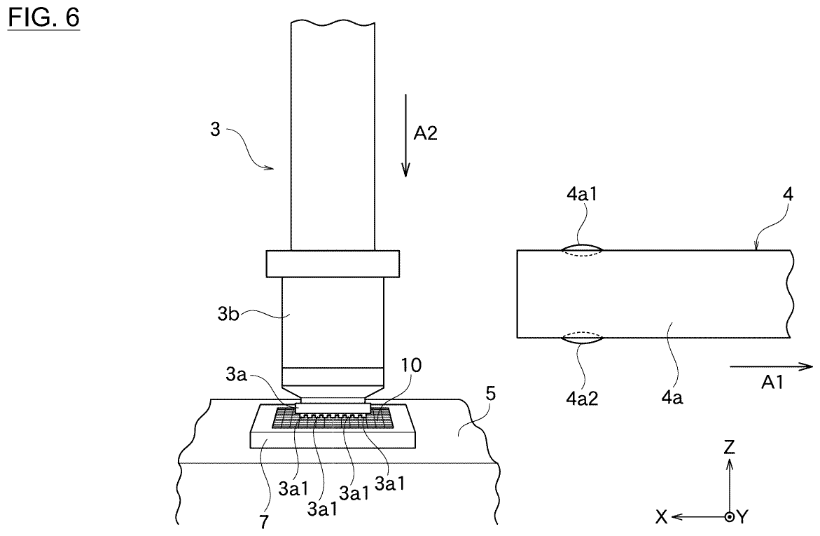

Then, the camera module 4 recedes in the direction of an arrow A1 in FIG. 6 along the X-axis. The camera module 4 waits at a location away from the head 3 in the X-axis direction. Then, the head 3 is lowered in the direction of an arrow A2 in FIG. 6 along the Z-axis. As the protrusions 3a1 of the workpiece holding part 3a come into contact with the workpieces 10, the head 3 stops. At this time, the workpieces 10 adhere to the protrusions 3a1 of the workpiece holding part 3a using adhesion. The workpiece holding part 3a thereby takes the workpieces 10 from the first substrate 7.

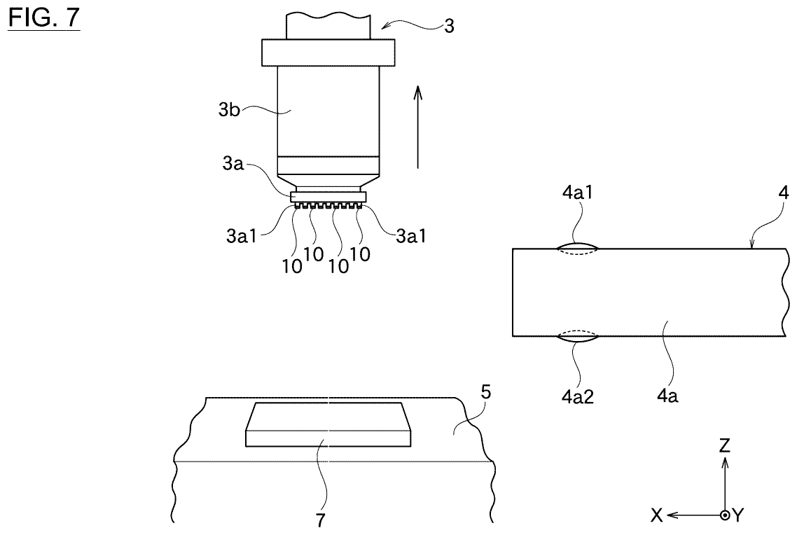

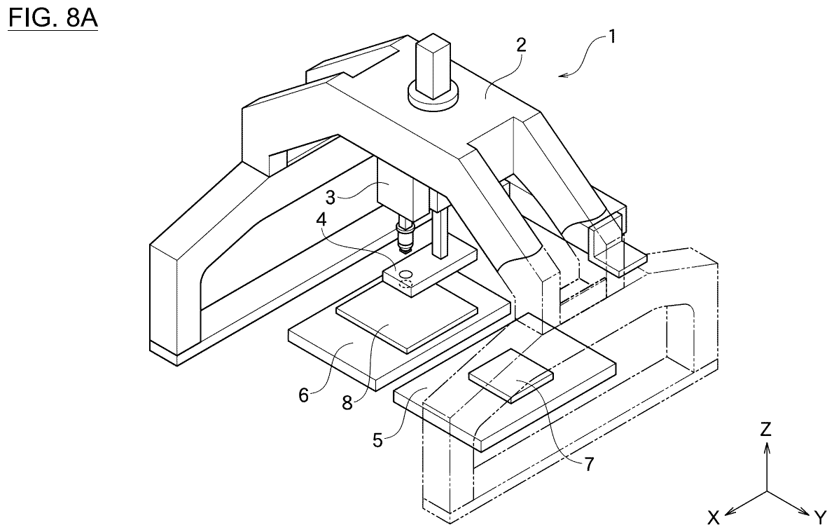

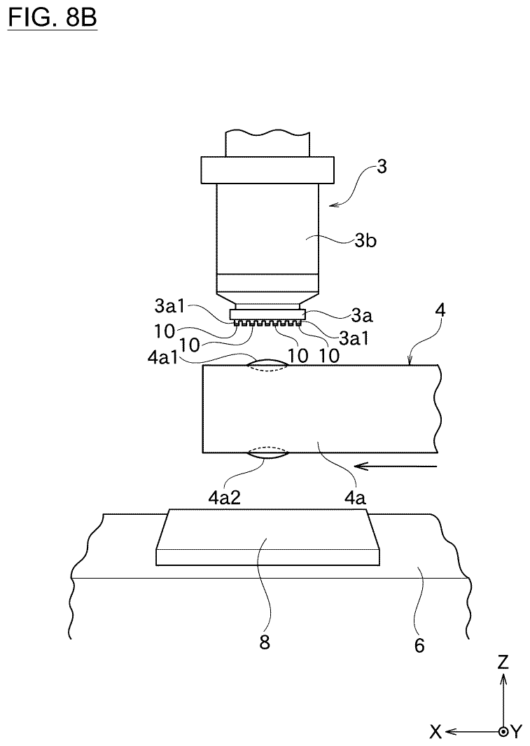

Then, the head 3 rises in the direction of an arrow in FIG. 7 along the Z-axis and waits at, for example, a location higher than that of the camera module 4. Then, as shown in FIG. 8A, the first stage 5 and the second stage 6 relocate at the same timing or at different timings. More specifically, the second stage 6 with the second substrate 8 moves to a location below the head 3. As the second substrate 8 is disposed directly below the head 3, the second stage 6 stops and waits there. The first stage 5 with the first substrate 7 moves to a location away from the head 3 (e.g., location adjacent to that of the second stage 6) and waits at that location.

Then, the camera module 4 proceeds in the direction of an arrow in FIG. 8B along the X-axis. As the imaging part 4a (the first lens 4a1 and the second lens 4a2) is disposed directly below the head 3 as shown in FIGS. 8A and 8B, the camera module 4 stops and takes an image at that location using the imaging part 4a. Using the first lens 4a1, the imaging part 4a takes an image of the extremity of the head 3 (workpiece holding part 3a) or the like. Using the second lens 4a2, the imaging part 4a takes an image of conditions of the second substrate 8, intended locations at which the workpieces 10 are intended to be mounted by the head 3, or the like. The camera module 4 transmits imaging information obtained by imaging by the imaging part 4a to the controller (not shown in the drawings) of the transfer apparatus 1.

In a situation where, for example, the location of the extremity of the head 3 (location of the workpiece holding part 3a) is misaligned in the X-axis direction or the Y-axis direction relative to the intended locations at which the workpieces 10 are intended to be mounted by the head 3, the controller transmits a control signal to the second stage 6 to control the location of the second stage 6 in the X-axis direction or the Y-axis direction. This enables the second substrate 8 on the second stage 6 to be disposed directly below the head 3. Note that the controller may transmit a control signal to the head 3 to control the location of the head 3 in the X-axis direction or the Y-axis direction.

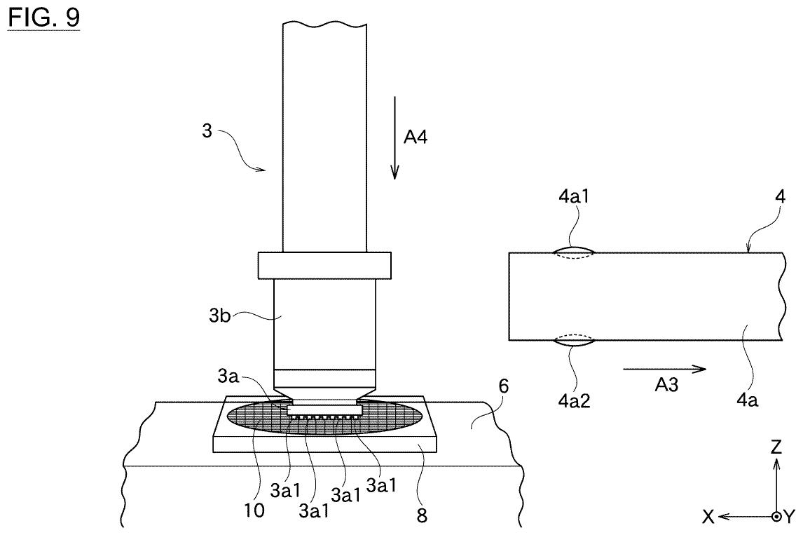

Then, the camera module 4 recedes in the direction of an arrow A3 in FIG. 9 along the X-axis. The camera module 4 waits at a location away from the head 3 in the X-axis direction. Then, the head 3 is lowered in the direction of an arrow A4 in FIG. 9 along the Z-axis. As the workpieces 10 adhered to the protrusions 3a1 of the workpiece holding part 3a come into contact with the second substrate 8, the head 3 stops. At this time, the workpiece holding part 3a may apply load or heat to the second substrate 8. The workpieces 10 adhered to the protrusions 3a1 thereby adhere to the intended locations of the second substrate 8 using adhesion. This enables the workpiece holding part 3a to mount the workpieces 10 on the second substrate 8.

Then, as shown in FIG. 10, the head 3 rises to move away from the second substrate 8 and stops at a location higher than that of the camera module 4. Note that, after the workpieces 10 are mounted on the second substrate 8 by the head 3, the camera module 4 may take an image of the locations at which the workpieces 10 are mounted, conditions of the second substrate 8 after the workpieces 10 are mounted thereon, or the like. In the above manner, the head 3 can take the workpieces 10 from the first substrate 7 (transfer source) with the workpieces 10 disposed thereon and mount them at predetermined locations on the second substrate 8 (transfer destination).

As shown in FIGS. 1A and 2A, the frame 2 of the transfer apparatus 1 of the present embodiment includes the upper body 20, to which the head 3 is fixed and which is curved in the arch shape toward the direction opposite the gravity direction. Thus, the weight of the upper body 20 or external load (e.g., load applied by the head 3) applied to the upper body 20 in the gravity direction is exerted on the upper body 20 as compressive stress that compresses the upper body 20 along its extending direction. This increases stiffness of the upper body 20 to make the upper body 20 less prone to bending. This can prevent variance, attributed to a bend of the upper body 20, in locations at which targets are mounted by the head 3. Thus, according to the present embodiment, the transfer apparatus 1 with which the targets can be mounted with high accuracy can be achieved.

The upper body 20 includes the upper pillars 25 and 27 in pairs and the upper beam 21, to which the head 3 is fixed and which bridges the space between the upper pillars 25 and 27 in pairs. One end of the upper beam 21 in its extending direction continues to the upper end of the upper pillar 25. The other end of the upper beam 21 in its extending direction continues to the upper end of the upper pillar 27. Moreover, the upper beam 21 is curved in the arch shape toward the direction opposite the gravity direction. In this situation, the curvature of the upper beam 21 can be controlled while the lengths of the upper pillars 25 and 27 in their axis direction can be controlled. This can optimize the height of the upper body 20 along the gravity direction. At the same time, this can prevent a bend of the upper beam 21 attributed to the weight of the upper beam 21 or external load applied to the upper beam 21 in the gravity direction.

The extremity of the head 3 (the workpiece holding part 3a or the base 3b) is located lower than the installation surface of the upper pillar 25 (faying surface between the upper pillar 25 and the lower body 40). In this situation, the center of gravity of the transfer apparatus 1 can be located at a low location. Thus, this can stabilize the balance of the transfer apparatus 1 to effectively prevent variance in locations at which targets are mounted by the head 3.

The upper beam 21 includes the first branch part 22; the second branch part 23, which is apart from the first branch part 22 in the X-axis direction; and the openings 35 and 36, which extend along the gravity direction between the first branch part 22 and the second branch part 23. Providing the upper beam 21 with the openings 35 and 36 can reduce the weight of the upper beam 21 to prevent a bend of the upper beam 21 attributed to its own weight.

As shown in FIGS. 1A and 2B, the frame 2 includes the lower body 40, which supports the upper body 20. The lower body 40 is curved in the arch shape toward the direction opposite the gravity direction. In this situation, the weight of the lower body 40 or external load (e.g., load applied by the upper body 20) applied to the lower body 40 in the gravity direction is exerted on the lower body 40 as compressive stress that compresses the lower body 40 along its extending direction. This increases stiffness of the lower body 40 to make the lower body 40 less prone to bending, enabling the lower body 40 to firmly support the upper body 20. Consequently, there is less fluctuation of the location of the upper body 20 along the gravity direction attributed to a bend of the lower body 40. This can effectively prevent variance in locations at which targets are mounted by the head 3.

The lower body 40 includes the lower pillars 42 and 43 in pairs and the lower beam 41, which supports the upper body 20 and bridges the space between the lower pillars 42 and 43 in pairs. One end of the lower beam 41 in its extending direction continues to the upper end of the lower pillar 42. The other end of the lower beam 41 in its extending direction continues to the upper end of the lower pillar 43. The lower beam 41 is curved in the arch shape toward the direction opposite the gravity direction. In this situation, the curvature of the lower beam 41 can be controlled while the lengths of the lower pillars 42 and 43 in their axis direction can be controlled. This can optimize the height of the lower body 40 along the gravity direction. At the same time, this can prevent a bend of the lower beam 41 attributed to the weight of the lower beam 41 or external load applied to the lower beam 41 in the gravity direction. This can also control the height of the frame 2 as a whole along the gravity direction according to the lengths of the lower pillars 42 and 43 in their axis direction.

The lower beam 41 is disposed orthogonal to the upper body 20. In this situation, it is possible for the lower beam 41 to support the upper body 20 in a well-balanced manner, enabling effective prevention of variance in locations at which targets are mounted by the head 3.

In recent years, in response to miniaturization of targets, or further in response to a requirement for higher accuracy in mounting the targets, improvement in image detection accuracy of the camera module 4 has been in demand. If the head 3 or the camera module 4 is fixed to the frame 2 without any measures being taken, the weight of the frame 2 or external load (e.g., load applied by the head 3 or the camera module 4) applied to the frame 2 in the gravity direction may cause the frame 2 to be bent (in particular, at the location at which the camera module 4 is fixed). This may cause a discrepancy in imaging information (e.g., imaging location in a horizontal direction) obtained by the camera module 4. This discrepancy may be a factor of variance in locations at which targets are mounted by the head 3. However, according to the present embodiment, the upper body 20 or the lower body 40 is less prone to bending, which can prevent a discrepancy, attributed to a bend of the upper body 20 or the lower body 40, in imaging information obtained by the camera module 4 as described above. Consequently, variance in locations at which targets are mounted by the head 3 can be prevented.

The present invention is not limited to the above embodiment and can be variously modified within the scope of the present invention. As shown in FIGS. 4A to 10, in the present embodiment, the location of the head 3 in the horizontal direction is fixed, whereas the first stage 5 with the first substrate 7 and the second stage 6 with the second substrate 8 move in the horizontal direction to a location below the head 3. However, the locations of the first stage 5 and the second stage 6 in the horizontal direction may be fixed, and the head 3 may move in the horizontal direction to the locations of the first stage 5 (first substrate 7) and the second stage 6 (second substrate 8).

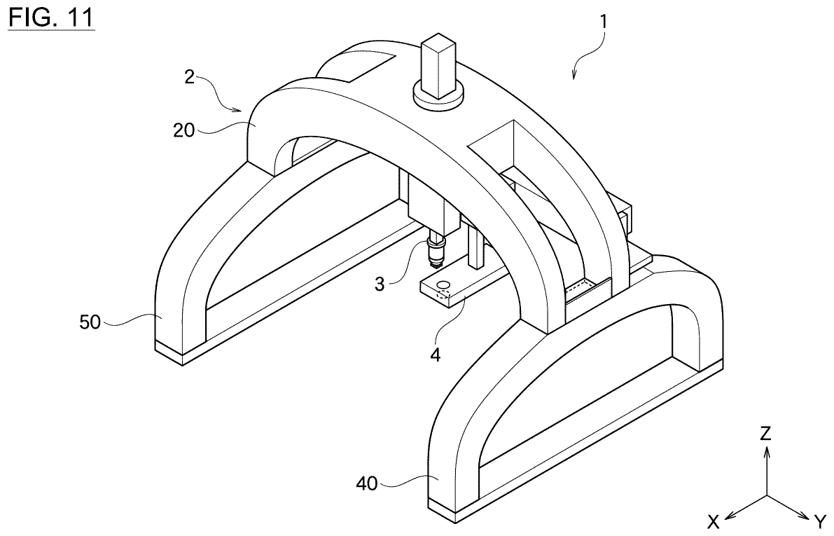

As shown in FIG. 11, the bends 31 to 34 may be omitted from the upper body 20 shown in FIG. 2A so that the upper body 20 is smoothly curved in an arch shape toward the direction opposite the gravity direction. Similarly, the bends 45 to 48 may be omitted from the lower body 40 shown in FIG. 2B so that the lower body 40 is smoothly curved in an arch shape toward the direction opposite the gravity direction. The same applies to the lower body 50.

As shown in FIGS. 5A, 5B, 8A, and 8B, the camera module 4 takes an image of the head 3, the first substrate 7, or the second substrate 8 at a location directly below the head 3. However, the camera module 4 may take an image of the head 3, the first substrate 7, or the second substrate 8 at a location away from the head 3 in the X-axis direction (location other than the location directly below the head 3). The camera module 4 may, for example, take an image of a raising or lowering operation of the head 3, a proceeding or receding operation of the first stage 5 or the second stage 6, or the like at a location away from the head 3 in the X-axis direction (e.g., as shown in FIGS. 4A and 4B, a location other than the location directly below the head 3). In this situation, the first lens 4a1 and the second lens 4a2 of the camera module 4 may include lenses that can cover a large field of view (wide-angle lenses).

In the above embodiment, the number of the transfer source substrate (first substrate 7) is one; however, the number of transfer source substrates may be plural. In this situation, stages (first stages 5) for installing the transfer source substrates may be prepared according to the number of the transfer source substrates.

As shown in FIG. 1A, the upper body 20 as a whole is curved in the arch shape toward the direction opposite the gravity direction. However, the upper body 20 may only partly be curved in an arch shape toward the direction opposite the gravity direction. The same applies to the lower body 40.

### REFERENCE NUMERALS

1 . . . transfer apparatus
2 . . . frame
3 . . . head
3a . . . workpiece holding part
3b . . . base
3c . . . driving part
4 . . . camera module
4a . . . imaging part
4b . . . driving part
5 . . . first stage
6 . . . second stage
7 . . . first substrate
8 . . . second substrate
9 . . . stand
10 . . . workpiece
20 . . . upper body
21 . . . upper beam
22 . . . first branch part
22a . . . top portion
22b, 22c . . . side portion
23 . . . second branch part
23a . . . top portion
23b, 23c . . . side portion
24 . . . head fixing part
25, 27 . . . upper pillar
26a, 26b, 28a, 28b . . . pillar body
29, 30 . . . upper fixing part
31 to 34 . . . bend
35, 36 . . . opening
40 . . . lower body
41 . . . lower beam
41a . . . top portion
41b, 41c . . . side portion
42, 43 . . . lower pillar
44 . . . lower fixing part
45 to 48 . . . bend
50 . . . lower body
51 . . . lower beam
51a . . . top portion
51b, 51c . . . side portion
52, 53 . . . lower pillar
54 . . . lower fixing part
70 . . . jig

1. A transfer apparatus comprising:
a frame; and
a head fixed to the frame and configured to transfer a target,
wherein the frame comprises an upper body provided with the head and curved in an arch shape toward a direction opposite a gravity direction.

2. The transfer apparatus according to claim 1, wherein
the upper body comprises
upper pillars in pairs, and
an upper beam provided with the head and bridging a space between the upper pillars in pairs,
one end of the upper beam in its extending direction continues to an end of one of the upper pillars in its axis direction,
an other end of the upper beam in its extending direction continues to an end of an other one of the upper pillars in its axis direction, and
the upper beam is curved in an arch shape toward the direction opposite the gravity direction.

3. The transfer apparatus according to claim 2, wherein an extremity of the head is located lower than an installation surface of the upper pillars.

4. The transfer apparatus according to claim 1, wherein the upper beam comprises a first branch part, a second branch part apart from the first branch part in a direction perpendicular to the gravity direction, and an opening extending along the gravity direction between the first branch part and the second branch part.

5. The transfer apparatus according to claim 1, wherein
the frame comprises a lower body supporting the upper body, and
the lower body is curved in an arch shape toward the direction opposite the gravity direction.

6. The transfer apparatus according to claim 5, wherein
the lower body comprises
lower pillars in pairs, and
a lower beam supporting the upper body and bridging a space between the lower pillars in pairs,
one end of the lower beam in its extending direction continues to an end of one of the lower pillars in its axis direction,
an other end of the lower beam in its extending direction continues to an end of an other one of the lower pillars in its axis direction, and
the lower beam is curved in an arch shape toward the direction opposite the gravity direction.

7. The transfer apparatus according to claim 6, wherein the lower beam is disposed orthogonal to the upper body.

8. The transfer apparatus according to claim 6, wherein a camera module comprising an imaging part and a driving part is three-dimensionally movably fixed to the lower beam.

9. The transfer apparatus according to claim 8, wherein the camera module is configured to take an image of a location at which the target is mountable by the head and a location of an extremity of the head.
